(19) United States
(12) Patent Application Publication
(10) Pub. No.: US 2025/0318184 A1
(43) Pub. Date: Oct. 9, 2025

(54) SEMICONDUCTOR DEVICE AND METHOD FOR MANUFACTURING THE SAME

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Keito TOUYAMA, Nonoichi (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/820,403

(22) Filed: Aug. 30, 2024

(30) Foreign Application Priority Data
Apr. 9, 2024 (JP) 2024-062947

(51) Int. Cl. H01L 29/78; H01L 29/40; H01L 29/66

(52) U.S. Cl. CPC H10D 30/668; H10D 30/0297; H10D 64/117

(57) ABSTRACT

According to one embodiment, a semiconductor device includes a first electrode, a first semiconductor region of a first conductivity type, a second semiconductor region of a second conductivity type, a third semiconductor region of the first conductivity type, a gate electrode, a metal layer, and a second electrode. The gate electrode faces the second semiconductor region via a gate insulating layer in a second direction. The second direction is perpendicular to a first direction from the first electrode toward the first semiconductor region. The metal layer is provided on the gate electrode via a first insulating layer. The metal layer includes at least one selected from the group consisting of titanium, lanthanum, and vanadium. The second electrode is provided on the metal layer via a second insulating layer. The second electrode is electrically connected to the second semiconductor region and the third semiconductor region.

### CROSS-REFERENCE TO RELATED APPLICATIONS

This application is based upon and claims the benefit of priority from Japanese Patent Application No. 2024-062947, filed on Apr. 9, 2024; the entire contents of which are incorporated herein by reference.

### FIELD

Embodiments of the present invention generally relate to a semiconductor device and a method for manufacturing the same.

### BACKGROUND

Semiconductor devices such as metal-oxide-semiconductor field effect transistors (MOSFETs) are used for power conversion and other applications. The semiconductor device can be switched to the on state by applying a voltage greater than the threshold to the gate electrode. It is desirable that the fluctuation of the threshold voltage of the semiconductor device is small.

### BRIEF DESCRIPTION OF THE DRAWINGS

FIG. 1 is a perspective cross-sectional view illustrating a semiconductor device according to an embodiment;

FIG. 2 is an enlarged cross-sectional view of a part of the semiconductor device according to the embodiment;

FIGS. 3A and 3B are cross-sectional views illustrating a method for manufacturing the semiconductor device according to the embodiment;

FIGS. 4A and 4B are cross-sectional views illustrating a method for manufacturing the semiconductor device according to the embodiment;

FIGS. 5A and 5B are cross-sectional views illustrating a method for manufacturing the semiconductor device according to the embodiment; and

FIG. 6 is a perspective cross-sectional view illustrating a semiconductor device according to a modification of the embodiment.

### DETAILED DESCRIPTION

According to one embodiment, a semiconductor device includes a first electrode, a first semiconductor region of a first conductivity type, a second semiconductor region of a second conductivity type, a third semiconductor region of the first conductivity type, a gate electrode, a metal layer, and a second electrode. The first semiconductor region is provided on the first electrode and electrically connected to the first electrode. The second semiconductor region is provided on the first semiconductor region. The third semiconductor region is provided on the second semiconductor region. The gate electrode faces the second semiconductor region via a gate insulating layer in a second direction. The second direction is perpendicular to a first direction from the first electrode toward the first semiconductor region. The metal layer is provided on the gate electrode via a first insulating layer. The metal layer includes at least one selected from the group consisting of titanium, lanthanum, and vanadium. The second electrode is provided on the metal layer via a second insulating layer. The second electrode is electrically connected to the second semiconductor region and the third semiconductor region.

Various embodiments will be described hereinafter with reference to the accompanying drawings. The drawings are schematic and conceptual; and the relationships between the thickness and width of portions, the proportions of sizes among portions, etc., are not necessarily the same as the actual values thereof. Further, the dimensions and proportions may be illustrated differently among drawings, even for identical portions. In the specification and drawings, components similar to those described or illustrated in a drawing thereinabove are marked with like reference numerals, and a detailed description is omitted as appropriate.

In the following descriptions and drawings, notations of n⁺, n⁻ and p⁺, p represent relative heights of impurity concentrations in conductivity types. That is, the notation with “+” shows a relatively higher impurity concentration than an impurity concentration for the notation without any of “+” and “−”. The notation with “−” shows a relatively lower impurity concentration than the impurity concentration for the notation without any of them. These notations represent relative height of a net impurity concentration after mutual compensation of these impurities when respective regions include both of a p-type impurity and an n-type impurity.

The embodiments described below may be implemented by reversing the p-type and the n-type of the semiconductor regions.

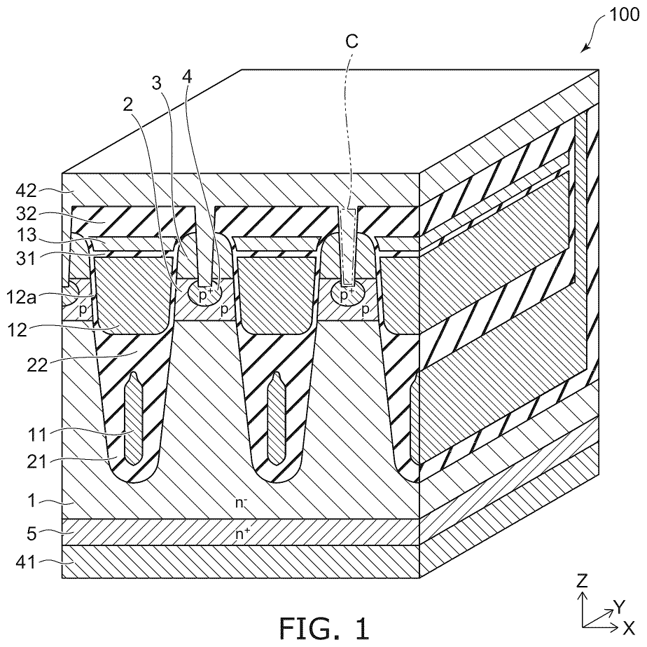

FIG. 1 is a perspective cross-sectional view illustrating a semiconductor device according to an embodiment.

As shown in FIG. 1, the semiconductor device 100 according to the embodiment includes an n⁻-type (a first conductivity type) drift region 1 (a first semiconductor region), a p-type (a second conductivity type) base region 2 (a second semiconductor region), an n⁺-type source region 3 (a third semiconductor region), a p⁺-type contact region 4, an n⁺-type drain region 5, a conductive portion 11, a gate electrode 12, a gate insulating layer 12a, a metal layer 13, a first insulating portion 21, a second insulating portion 22, a first insulating layer 31, a second insulating layer 32, a drain electrode 41 (a first electrode), and a source electrode 42 (a second electrode). The semiconductor device 100 is a MOSFET.

An XYZ orthogonal coordinate system is used in the description of the embodiments. The direction from the drain electrode 41 toward the n⁻-type drift region 1 is taken as a Z-direction (a first direction). Two mutually-orthogonal directions perpendicular to the Z-direction are taken as an X-direction (a second direction) and a Y-direction. In the description, the direction from the drain electrode 41 toward the n-type drift region 1 is called “up/above/higher than”, and the opposite direction is called “down/below/lower than”. These directions are based on the relative positional relationship between the drain electrode 41 and the n-type drift region 1 and are independent of the direction of gravity.

The drain electrode 41 is provided in the lower part of the semiconductor device 100. The n⁺-type drain region 5 is provided on the drain electrode 41 and is electrically connected to the drain electrode 41. The n-type drift region 1 is provided on the n⁺-type drain region 5. The n-type impurity concentration in the n-type drift region 1 is lower than the n-type impurity concentration in the n⁺-type drain region 5.

The p-type base region 2 is provided on the n-type drift region 1. The n⁺-type source region 3 and the p⁺-type contact region 4 are provided on the p-type base region 2. The n-type impurity concentration in the n⁺-type source region 3 is greater than the n-type impurity concentration in the n-type drift region 1. The p-type impurity concentration in the p⁺-type contact region 4 is greater than the p-type impurity concentration in the p-type base region 2.

The conductive portion 11 is provided via the first insulating portion 21 in the n-type drift region 1. The gate electrode 12 is provided on the conductive portion 11 via the second insulating portion 22. The gate electrode 12 faces the p-type base region 2 via the gate insulating layer 12a in the X-direction. The gate electrode 12 may be further facing a part of the n-type drift region 1 and a part of the n⁺-type source region 3 via the gate insulating layer 12a.

The metal layer 13 is provided on the gate electrode 12 via the first insulating layer 31. The source electrode 42 is provided on the metal layer 13 via the second insulating layer 32. The source electrode 42 is provided on the p-type base region 2 and the n⁺-type source region 3, and is electrically connected to the p-type base region 2 and the n⁺-type source region 3.

As shown in FIG. 1, the source electrode 42 may include a contact portion C. The contact portion C is arranged with a part of the p-type base region 2 and the n⁺-type source region 3 in the X-direction and is located on the p⁺-type contact region 4. The contact portion C is in contact with the p-type base region 2, the n⁺-type source region 3, and the p⁺-type contact region 4.

An example of the material of each component will be described.

The n⁻-type drift region 1, the p-type base region 2, the n⁺-type source region 3, the p⁺-type contact region 4, and the n⁺-type drain region 5 include silicon, silicon carbide, gallium nitride, or gallium arsenide as a semiconductor material. When silicon is used as the semiconductor material, arsenic, phosphorus, or antimony can be used as an n-type impurity. Boron can be used as a p-type impurity. The conductive portion 11 and the gate electrode 12 include a conductive material such as polysilicon. The metal layer 13 includes one or more selected from the group consisting of titanium (Ti), lanthanum (La), and vanadium (V). The metal layer 13 may contain a compound of one or more selected from the group consisting of titanium, lanthanum, and vanadium. An example of the compound is TiFe. Preferably, the metal layer 13 consists of only titanium. The gate insulating layer 12a, the first insulating portion 21, the second insulating portion 22, the first insulating layer 31, and the second insulating layer 32 include an insulating material such as silicon oxide, silicon nitride, or silicon oxynitride. The drain electrode 41 and the source electrode 42 include a metal such as titanium, aluminum, or copper.

The operation of the semiconductor device 100 will be described.

A voltage exceeding the threshold is applied to the gate electrode 12 in a state where a positive voltage applied to the drain electrode 41 with respect to the source electrode 42. As a result, a channel (inverting layer) is formed in the p-type base region 2, and the semiconductor device 100 is turned on. Electrons flow from the source electrode 42 to the drain electrode 41 through the channel. When the voltage applied to the gate electrode 12 becomes lower than the threshold, the channel in the p-type base region 2 disappears and the semiconductor device 100 is turned off.

When the semiconductor device 100 switches to the off-state, the positive voltage applied to the drain electrode 41 with respect to the source electrode 42 increases. The potential of the conductive portion 11 is substantially the same as the potential of the source electrode 42. The n-type drift region 1 is electrically connected to the drain electrode 41. Due to the electric potential difference between the n⁻-type drift region 1 and the conductive portion 11, the depletion layer spreads from the interface between the first insulating portion 21 and the n-type drift region 1 toward the n⁻-type drift region 1. By the spreading of the depletion layer, the breakdown voltage of the semiconductor device 100 can be increased. Alternatively, while maintaining the breakdown voltage of the semiconductor device 100, the n-type impurity concentration in the n-type drift region 1 can be increased, and the on-resistance of the semiconductor device 100 can be reduced.

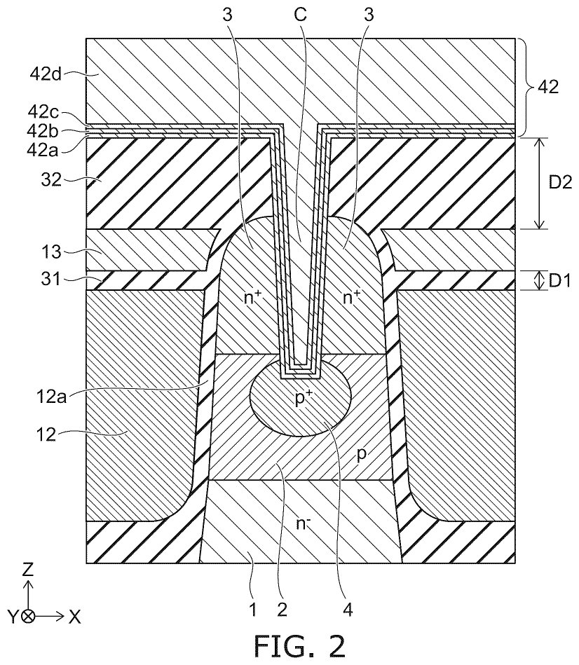

FIG. 2 is an enlarged cross-sectional view of a part of the semiconductor device according to the embodiment.

As shown in FIG. 2, the source electrode 42 may include multiple metal layers. In the example shown in FIG. 2, the source electrode 42 includes a titanium layer 42a, a titanium nitride layer 42b, a tungsten layer 42c, and an aluminum copper layer 42d. The titanium layer 42a is in contact with the p-type base region 2, the n⁺-type source region 3, and the p⁺-type contact region 4. The titanium nitride layer 42b is provided on the titanium layer 42a. The tungsten layer 42c is provided on the titanium nitride layer 42b. The aluminum copper layer 42d is provided on the tungsten layer 42c.

The distance D1 in the Z-direction between the gate electrode 12 and the metal layer 13 is shorter than the distance D2 in the Z-direction between the metal layer 13 and the source electrode 42. The distance D1 corresponds to the thickness of the first insulating layer 31. The distance D2 corresponds to the thickness of the second insulating layer 32.

As shown in FIG. 1, each of the p-type base region 2, the n⁺-type source region 3, the p⁺-type contact region 4, the conductive portion 11, the gate electrode 12, and the contact portion C is provided in a plurality in the X-direction. For example, a pair of n⁺-type source regions 3 are provided on one p-type base region 2. One contact portion C is positioned between the pair of n⁺-type source regions 3 in the X-direction. The gate electrode 12 and a group of p-type base region 2, the pair of n⁺-type source regions 3, and the p⁺-type contact region 4 is alternately provided in the X-direction.

Each p-type base region 2, each n⁺-type source region 3, each p⁺-type contact region 4, each conductive portion 11, each gate electrode 12, and each contact portion C extend in the Y-direction and are arranged in a stripe shape. An end portion of the conductive portion 11 in the Y-direction is provided upward and is in contact with the source electrode 42. Thereby, the conductive portion 11 is electrically connected to the source electrode 42.

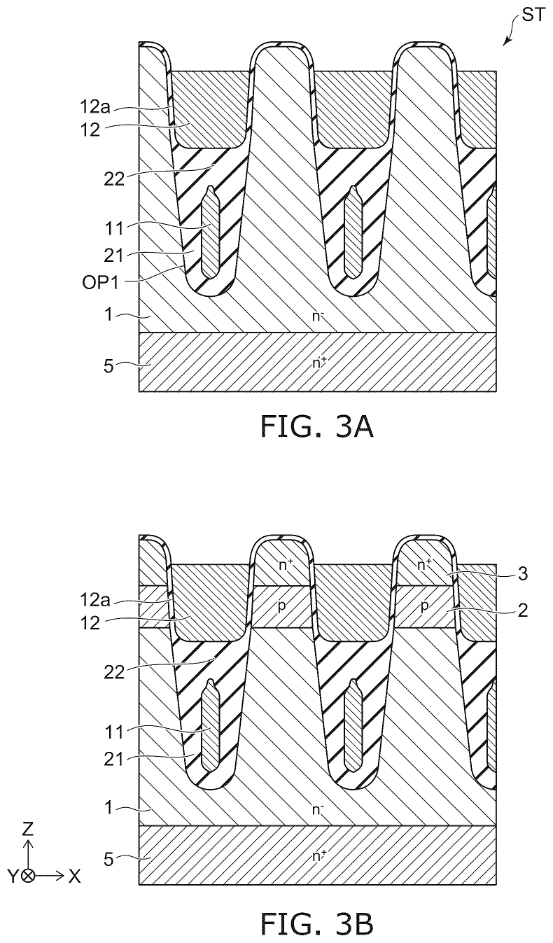

FIGS. 3A, 3B, 4A, 4B, 5A, and 5B are cross-sectional views illustrating a method for manufacturing the semiconductor device according to the embodiment.

First, a semiconductor substrate including an n-type drift region 1 and an n⁺-type drain region 5 is prepared. Multiple openings OP1 are formed on the upper surface of the n-type drift region 1 using a known method. As shown in FIG. 3A, the conductive portion 11, the gate electrode 12, the gate insulating layer 12a, the first insulating portion 21, and the second insulating portion 22 are formed inside the opening OP1. As a result, a structure body ST including the n-type drift region 1, the n⁺-type drain region 5, the conductive portion 11, the gate electrode 12, the gate insulating layer 12a, the first insulating portion 21, and the second insulating portion 22 is prepared.

P-type impurities and n-type impurities are sequentially ion-implanted into the part of the n-type drift region 1 positioned between the openings OP1. Thereby, as shown in FIG. 3B, the p-type base region 2 and the n⁺-type source region 3 are formed on the n-type drift region 1.

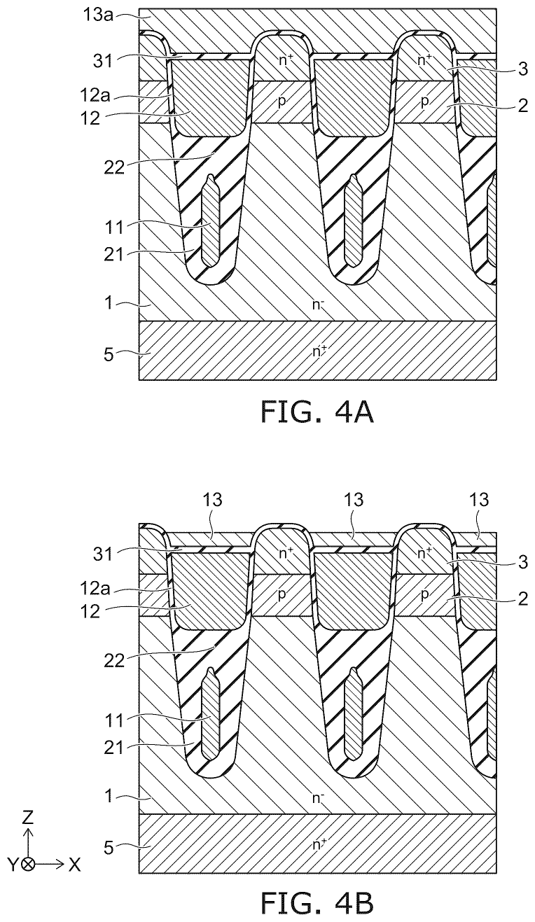

The first insulating layer 31 is formed on the upper surface of the gate electrode 12 by thermal oxidation. As shown in FIG. 4A, the metal layer 13a including titanium is formed on the first insulating layer 31 by chemical vapor deposition (CVD). The upper surface of the metal layer 13a is caused to be retreated by reactive ion etching (RIE). As a result, as shown in FIG. 4B, the metal layer 13 is formed on each gate electrode 12.

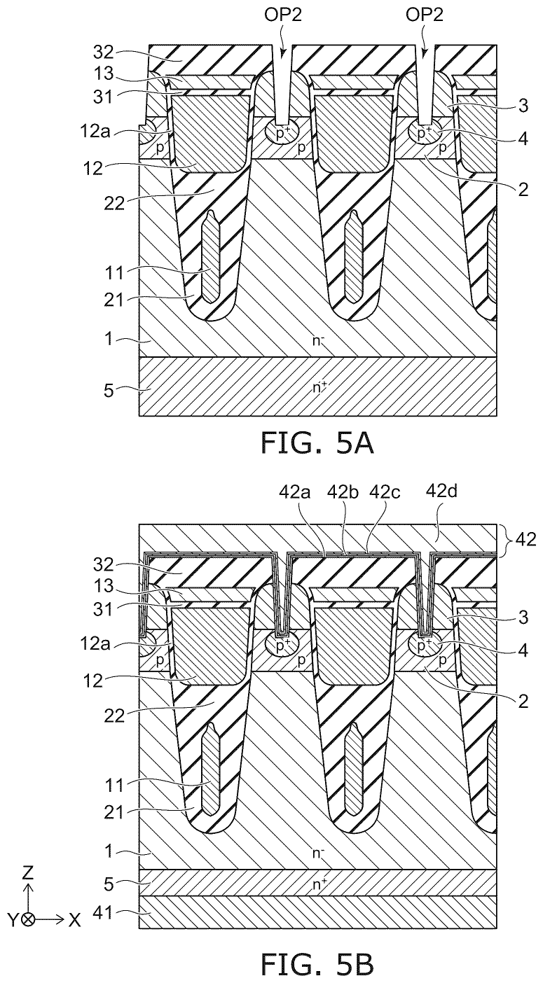

A second insulating layer 32 is formed on the metal layer 13 by CVD. A part of each second insulating layer 32, a part of each n⁺-type source region 3, and a part of each p-type base region 2 are removed to form multiple openings OP2 by RIE. Through the openings OP2, p-type impurities are ion-implanted into the p-type base regions 2. As a result, as shown in FIG. 5A, the p⁺-type contact regions 4 are formed.

The titanium layer 42a to tungsten layer 42c are sequentially formed along the upper surface of the second insulating layer 32 and the inner surfaces of the openings OP2 by CVD. The aluminum copper layer 42d is formed by sputtering. As a result, the source electrode 42 including the titanium layer 42a to aluminum copper layer 42d is formed. The back surface of the n+drain region 5 is ground until the n⁺-type drain region 5 reaches a predetermined thickness. As shown in FIG. 5B, the drain electrode 41 is formed on the ground back surface of the n⁺-type drain region 5 by sputtering. According to the above steps, the semiconductor device 100 according to the embodiment is manufactured.

The semiconductor device 100 is heat-treated in a hydrogen atmosphere after forming the drain electrode 41 and the source electrode 42. As a result, dangling bonds existing at the interface between the n-type drift region 1 and the first insulating portion 21, the interface between the p-type base region 2 and the gate insulating layer 12a, the interface between the n⁺-type source region 3 and the gate insulating layer 12a, etc. are terminated. By terminating the dangling bonds, it is possible to suppress unintended impurities from binding to the dangling bonds and affecting the characteristics of the semiconductor device 100.

Advantages of the embodiment will now be described.

Hydrogen existing at the interfaces described above can be desorbed by application of voltage during the operation of the semiconductor device 100. When hydrogen is desorbed, silicon dangling bonds are generated, and traps for holes are formed. When holes are trapped, the threshold voltage for turning on the semiconductor device 100 fluctuates. In addition, there is a possibility that an unintended impurity binds to the dangling bonds and the characteristics of the semiconductor device 100 fluctuate.

The semiconductor device 100 according to the embodiment includes the metal layer 13 to address this issue. The metal layer 13 is provided on the gate electrode 12 and includes one or more selected from the group consisting of titanium, lanthanum, and vanadium. Titanium, lanthanum, or vanadium easily absorbs hydrogen. When the metal layer 13 is provided, hydrogen absorbed by titanium, lanthanum, or vanadium diffuses from the metal layer 13. Therefore, even if hydrogen is desorbed and silicon dangling bonds are generated, hydrogen diffused from the metal layer 13 is supplied to the dangling bonds. For example, dangling bonds are terminated by the supplied hydrogen. Therefore, according to the embodiment, fluctuation in the threshold voltage caused by the desorption of hydrogen can be suppressed.

The metal layer 13 is preferably separated from the gate electrode 12 by the first insulating layer 31. When the metal layer 13 is in contact with the gate electrode 12, the metal contained in the metal layer 13 may react with the silicon of the gate electrode 12, and silicide may be formed. The storage capacity of hydrogen in silicide is less than the storage capacity of hydrogen in the metal alone. Thus, in order to suppress the fluctuation in the threshold, it is effective to separate the metal layer 13 from the gate electrode 12 and suppress the formation of silicide in the metal layer 13.

A contact may be provided between a part of the gate electrode 12 and a part of the metal layer 13, and the gate electrode 12 and the metal layer 13 may be electrically connected. However, more preferably, the metal layer 13 is electrically isolated from the gate electrode 12. When the metal layer 13 is electrically connected to the gate electrode 12, the capacitance Cos between the gate electrode 12 and the source electrode 42 is increased compared to when the metal layer 13 is not provided. Even when the metal layer 13 is provided, the increase in capacity Cos can be suppressed by electrically isolating the metal layer 13 and the gate electrode 12.

The metal layer 13 may be connected to an electric potential other than the electric potentials of the gate electrode 12 and the source electrode 42. Preferably, the electric potential of the metal layer 13 is floating. By making the electric potential of the metal layer 13 floating, the structure of the semiconductor device 100 can be simplified.

The metal layer 13 is preferably located near the interface between the p-type base region 2 and the gate insulating layer 12a. Since the metal layer 13 is located near the interface, hydrogen diffused from the metal layer 13 is easily supplied to the interface. For example, as shown in FIG. 2, the distance D1 between the gate electrode 12 and the metal layer 13 is shorter than the distance D2 between the metal layer 13 and the source electrode 42. This allows the metal layer 13 to be located closer to the interface between the p-type base region 2 and the gate insulating layer 12a. As a result, the fluctuation in the threshold voltage caused by the desorption of hydrogen can be further suppressed. For example, the distance D1 is preferably not less than 10 nm and not more than 100 nm, and more preferably not less than 30 nm and not more than 80 nm.

The thickness of the metal layer 13 can be freely designed as long as a sufficient amount of hydrogen can be stored. For example, the thickness of the metal layer 13 is preferably not less than 8 nm and not more than 180 nm, and more preferably not less than 8 nm and not more than 150 nm.

The upper end of the metal layer 13 is preferably positioned lower than the upper end of the n⁺-type source region 3. When the metal layer 13 is positioned higher than the p-type base region 2, the second insulating layer 32 and the source electrode 42 are positioned higher by the thickness of the metal layer 13. For example, in the step shown in FIG. 5A, there is a possibility that the opening OP2 may be difficult to form. When the upper end of the metal layer 13 is positioned lower than the upper end of the n⁺-type source region 3, the manufacture of the semiconductor device 100 becomes easier. In addition, when the upper end of the metal layer 13 is positioned lower than the upper end of the n⁺-type source region 3, the metal layer 13 is located closer to the gate electrode 12. As a result, the fluctuation in the threshold voltage caused by hydrogen desorption can be effectively suppressed.

The source electrode 42 preferably includes a titanium layer 42a, as shown in FIG. 2. The titanium layer 42a can store hydrogen as well. By supplying hydrogen to the silicon dangling bonds from both the metal layer 13 and the titanium layer 42a, the fluctuation in the threshold voltage in the semiconductor device 100 can be further suppressed.

Among titanium, lanthanum, and vanadium, titanium is the most preferable for the metal used in the metal layer 13. This is because titanium absorbs hydrogen more easily than lanthanum and vanadium.

The source electrode 42 preferably includes the contact portion C, as shown in FIG. 1. By providing the contact portion C, the contact area between the p-type base region 2 (the p⁺-type contact region 4) and the source electrode 42, and the contact area between the n⁺-type source region 3 and the source electrode 42 can be increased.

### Modification

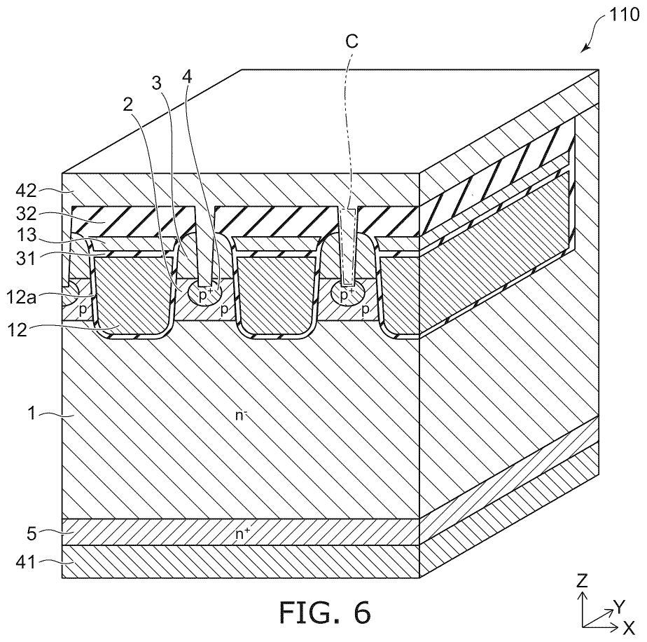

FIG. 6 is a perspective cross-sectional view illustrating a semiconductor device according to a modification of the embodiment.

As shown in FIG. 6, the semiconductor device 110 according to the modification includes the n-type drift region 1, the p-type base region 2, the n⁺-type source region 3, the p⁺-type contact region 4, the n⁺-type drain region 5, the gate electrode 12, the gate insulating layer 12a, the metal layer 13, the first insulating layer 31, the second insulating layer 32, the drain electrode 41, and the source electrode 42. The semiconductor device 110 differs from the semiconductor device 100 by not including the conductive portion 11.

The gate electrode 12 is provided in the n-type drift region 1 via the gate insulating layer 12a. The gate electrode 12 faces the p-type base region 2 in the X-direction via the gate insulating layer 12a.

In order to improve the breakdown voltage of the semiconductor device 100 or to reduce the on-resistance, it is desirable that the conductive portion 11 is provided. However, when the conductive portion 11 can be omitted in terms of breakdown voltage or on-resistance, the conductive portion 11 may be omitted as in the semiconductor device 110.

Embodiments of the present invention include the following features.

### Feature 1

A semiconductor device, comprising:
a first electrode;
a first semiconductor region provided on the first electrode and electrically connected to the first electrode, the first semiconductor region being of a first conductivity type;
a second semiconductor region provided on the first semiconductor region and being a second conductivity type;
a third semiconductor region provided on the second semiconductor region and being of the first conductivity type;
a gate electrode facing the second semiconductor region via a gate insulating layer in a second direction, the second direction being perpendicular to a first direction from the first electrode toward the first semiconductor region;
a metal layer provided on the gate electrode via a first insulating layer, the metal layer including at least one selected from the group consisting of titanium, lanthanum, and vanadium;
a second electrode provided on the metal layer via a second insulating layer, the second electrode being electrically connected to the second semiconductor region and the third semiconductor region.

### Feature 2

The semiconductor device according to feature 1, wherein
the metal layer is electrically isolated from the gate electrode and the second electrode.

### Feature 3

The semiconductor device according to feature 1 or 2, wherein
an electric potential of the metal layer is floating.

### Feature 4

The semiconductor device according to any one of features 1 to 3, wherein
a distance in the first direction between the gate electrode and the metal layer is shorter than a distance in the first direction between the metal layer and the second electrode.

### Feature 5

The semiconductor device according to any one of features 1 to 4, wherein
an upper end of the metal layer is positioned lower than an upper end of the third semiconductor region.

### Feature 6

The semiconductor device according to any one of features 1 to 5, wherein
the second electrode includes a titanium layer in contact with the second semiconductor region and the third semiconductor region.

### Feature 7

The semiconductor device according to any one of features 1 to 6, wherein
the metal layer includes titanium.

### Feature 8

The semiconductor device according to any one of features 1 to 7, further comprising a conductive portion provided in the first semiconductor region via a first insulating portion,
the gate electrode being provided on the conductive portion via a second insulating portion.

### Feature 9

A method of manufacturing a semiconductor device, comprising:
forming a metal layer on a structure body, the structure body including
   a first semiconductor region of a first conductivity type,
   a second semiconductor region of a second conductivity type on the first semiconductor region,
   a third semiconductor region of the first conductivity type on the second semiconductor region, and
   a gate electrode facing the second semiconductor region via a gate insulating layer in a second direction, the second direction being perpendicular to a first direction from the first semiconductor region toward the second semiconductor region,
the metal layer being formed on the gate electrode via a first insulating layer and including at least one selected from the group consisting of titanium, lanthanum, and vanadium;
forming a second insulating layer on the metal layer; and
forming an electrode on the second insulating layer.

It is possible to confirm the relative levels of the impurity concentrations of the semiconductor regions in the embodiments described above, for example, using a scanning capacitance microscope (SCM). The carrier concentrations of the semiconductor regions may be considered to be equal to the activated impurity concentrations of the semiconductor regions. Accordingly, the relative levels of the carrier concentrations of the semiconductor regions can be confirmed using SCM. It is possible to measure the impurity concentrations of the semiconductor regions, for example, using a secondary ion mass spectrometer (SIMS).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Moreover, above-mentioned embodiments can be combined mutually and can be carried out.

What is claimed is:

1. A semiconductor device, comprising:
a first electrode;
a first semiconductor region provided on the first electrode and electrically connected to the first electrode, the first semiconductor region being of a first conductivity type;
a second semiconductor region provided on the first semiconductor region and being a second conductivity type;
a third semiconductor region provided on the second semiconductor region and being of the first conductivity type;
a gate electrode facing the second semiconductor region via a gate insulating layer in a second direction, the second direction being perpendicular to a first direction from the first electrode toward the first semiconductor region;
a metal layer provided on the gate electrode via a first insulating layer, the metal layer including at least one selected from the group consisting of titanium, lanthanum, and vanadium;
a second electrode provided on the metal layer via a second insulating layer, the second electrode being electrically connected to the second semiconductor region and the third semiconductor region.

2. The semiconductor device according to claim 1, wherein
the metal layer is electrically isolated from the gate electrode and the second electrode.

3. The semiconductor device according to claim 1, wherein
an electric potential of the metal layer is floating.

4. The semiconductor device according to claim 1, wherein
a distance in the first direction between the gate electrode and the metal layer is shorter than a distance in the first direction between the metal layer and the second electrode.

5. The semiconductor device according to claim 1, wherein
an upper end of the metal layer is positioned lower than an upper end of the third semiconductor region.

6. The semiconductor device according to claim 1, wherein
the second electrode includes a titanium layer in contact with the second semiconductor region and the third semiconductor region.

7. The semiconductor device according to claim 1, wherein
the metal layer includes titanium.

8. The semiconductor device according to claim 1, further comprising a conductive portion provided in the first semiconductor region via a first insulating portion,
the gate electrode being provided on the conductive portion via a second insulating portion.

9. A method of manufacturing a semiconductor device, comprising:
forming a metal layer on a structure body, the structure body including
a first semiconductor region of a first conductivity type,
a second semiconductor region of a second conductivity type on the first semiconductor region,
a third semiconductor region of the first conductivity type on the second semiconductor region, and
a gate electrode facing the second semiconductor region via a gate insulating layer in a second direction, the second direction being perpendicular to a first direction from the first semiconductor region toward the second semiconductor region,
the metal layer being formed on the gate electrode via a first insulating layer and including at least one selected from the group consisting of titanium, lanthanum, and vanadium;
forming a second insulating layer on the metal layer; and
forming an electrode on the second insulating layer.
